(19) United States
(12) Patent Application Publication
(10) Pub. No.: US 2026/0280563 A1
(43) Pub. Date: Sep. 17, 2026

(54) OUTPUT CIRCUIT

(71) Applicant: Socionext Inc., Kanagawa (JP)

(72) Inventor: Kunihiro ITO, Yokohama-shi (JP)

(21) Appl. No.: 19/669,083

(22) Filed: May 6, 2026

Related U.S. Application Data
(63) Continuation of application No. PCT/JP2023/043586, filed on Dec. 6, 2023.

(51) Int. Cl. H03K 19/017; H03K 19/0185

(52) U.S. Cl. CPC H03K 19/01721; H03K 19/018521

(57) ABSTRACT

An output circuit includes a plurality of output drive circuits connected to an output node, and each output drive circuit includes a plurality of output buffers. Each output buffer includes: a first transistor of a first conductivity type and a first resistor provided in series with each other between a first power supply node and the output node; and a second transistor of a second conductivity type provided in series with the first resistor between a second power supply node and the output node. One of the first transistor and the second transistor is activated and the other is deactivated based on a first control signal.

### CROSS-REFERENCE TO RELATED APPLICATIONS

This is a continuation of International Application No. PCT/JP2023/043586 filed on Dec. 6, 2023. The entire disclosure of this application is incorporated by reference herein.

### BACKGROUND

The present disclosure relates to an output circuit that outputs a signal outside a semiconductor device (large scale integration (LSI)).

In recent years, many inter-LSI interface specifications are available along with a variety of LSI mounting structures, and also available are techniques for transmitting high-speed data in gigabit units. Output circuits for high-speed data transmission are especially required to respond to the specifications of output impedance.

For example, U.S. Pat. No. 7,961,008 (Patent Document 1) discloses an output circuit in which a plurality of circuit blocks (drive units) having predetermined output impedance values are arranged and operated selectively thereby achieving a plurality of output impedance characteristics. U.S. Pat. No. 11,404,094 (Patent Document 2) discloses an output circuit in which transistors of different conductivity types are arranged in a mixed manner in an output driver and operated selectively thereby achieving a plurality of frequency characteristics and voltage characteristics.

However, there has not been disclosed any prior art example in which an output circuit like the one of Patent Document 2 includes drive units like the ones in Patent Document 1 for achieving a plurality of output impedance characteristics.

An objective of the present disclosure is providing an output circuit that can respond to various output characteristics, curbs the increase in area, and operates at high speed.

### SUMMARY

According to the first mode of the disclosure, an output circuit configured to output an output signal responsive to an input signal from an output node includes a plurality of output drive circuits connected to the output node, wherein each of the output drive circuits includes a plurality of output buffers, each of the output buffers includes a first transistor of a first conductivity type and a first resistor provided in series with each other between a first power supply node and the output node, and a second transistor of a second conductivity type provided in series with the first resistor between a second power supply node and the output node, and one of the first transistor and the second transistor is activated, and the other is deactivated, based on a first control signal.

According to the above mode, in each output drive circuit, a first transistor of a first conductivity type is provided between a first power supply node and an output node, and a second transistor of a second conductivity type is provided between a second power supply node and the output node. In this way, by providing transistors of different conductivity types in a mixed manner, the number of units of output drive circuits can be reduced in comparison with the case of constituting output drive circuits corresponding to transistors of one conductivity type and to transistors of the other conductivity type individually. With the reduction in the number of units, the occupied area of the output circuit can be reduced.

Also, the first transistor and the second transistor share the first resistor. Therefore, the number of resistive elements used can be reduced, and this can reduce the occupied area of the output circuit. As the resistance value per unit of the output drive circuits is larger, the occupied area of the resistive elements used will expand. In such a case, therefore, the effect of reducing the occupied area will be exhibited more significantly. Moreover, with reduction in the area of placement of resistive elements, the parasitic capacitance to the output node is reduced, and this speeds up the transition (slew rate) of the output signal. With this, a waveform excellent in the openings of the so-called eye pattern (eye diagram) is obtained, permitting output of a high-speed signal short in cycle time.

According to the above mode, in each output drive circuit, the transistors of different conductivity types are operated selectively. With this, a full-amplitude output signal and a small-amplitude output signal can be generated. The small-amplitude output signal is effective in outputting a high-speed signal. Moreover, in this mode, the first power supply node and the second power supply node are separately provided to offer variations. With this, the output signal conforming to a wide variety of external interface specifications can be output.

The output circuit according to the present disclosure can respond to various output characteristics, curbs the increase in area, and can operate at high speed.

### BRIEF DESCRIPTION OF THE DRAWINGS

FIG. 1 is a block diagram showing an example of the configuration of an output circuit according to the first embodiment.

FIG. 2 is a circuit diagram showing an example of the configuration of an output drive circuit according to the first embodiment.

FIG. 3 is a block diagram showing an example of the configuration of a data processing part according to the first embodiment.

FIG. 4 is a circuit diagram showing an example of the configuration of the data processing part according to the first embodiment.

FIG. 5 is a truth table showing an operation example of the data processing part.

FIG. 6 is a block diagram showing an example of the configuration of an output circuit according to the second embodiment.

FIG. 7 is a circuit diagram showing an example of the configuration of an output drive circuit according to the second embodiment.

FIG. 8 is a block diagram showing an example of the configuration of a data processing part according to the second embodiment.

FIG. 9 is a circuit diagram showing an example of the configuration of the data processing part according to the second embodiment.

FIG. 10 is a circuit diagram showing an example of the configuration of an output drive circuit according to the third embodiment.

FIG. 11 is a circuit diagram showing an example of the configuration of an output drive circuit according to the fourth embodiment.

FIG. 12 is a block diagram showing an example of the configuration of an output circuit according to the fifth embodiment.

FIG. 13 is a circuit diagram showing an example of the configuration of an output drive circuit according to the fifth embodiment.

FIG. 14 is a block diagram showing an example of the configuration of a data processing part according to the fifth embodiment.

FIG. 15 is a circuit diagram showing an example of the configuration of the data processing part according to the fifth embodiment.

FIG. 16 is a block diagram showing an alteration of the data processing part according to the first embodiment.

FIG. 17 is a circuit diagram showing the alteration of the data processing part according t the first embodiment.

FIG. 18 is a circuit diagram showing an alteration of the output drive circuit according to the first embodiment.

FIG. 19 is a view showing an example of output signal waveforms output from an output terminal.

FIG. 20 is a view showing an example of output impedance characteristics.

### DETAILED DESCRIPTION

Embodiments of the present disclosure will be described hereinafter. Note that specific numerical values and the like indicated in the following embodiments are mere examples for facilitating the understanding of the disclosure and by no means intended to limit the scope of the disclosure.

In the following description, nodes and terminals of a circuit and signals passing through such nodes and terminals may be described under the same reference characters, and a power supply and a power supply voltage of the power supply may be described under the same reference character. Also, the voltages of nodes and terminals may be described as “(terminal or node name)=(character indicating voltage).” To state specifically, when the voltage of an output node out is VDD1 (voltage of a power supply VDD1), it may be described as out=VDD1. Similarly, the signals of nodes and terminals may be described as “(signal name)=(state of signal).” Also, a gate-source voltage Vgs of a transistor may be described as “Vgs” simply.

### First Embodiment

An output circuit 1 is a circuit that outputs an output signal out responsive to an input signal in input through an input terminal IN to the outside of the LSI through an output terminal OUT.

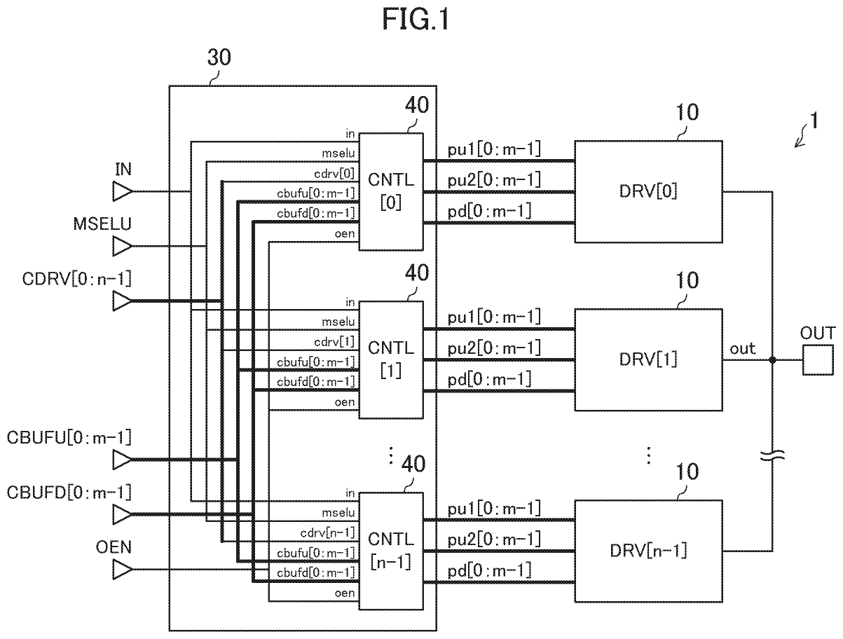

As shown in FIG. 1, the output circuit 1 includes: a plurality of output drive circuits 10 connected to an output node out; and an output control circuit 30. The output circuit 1 of FIG. 1 includes n (n: natural number) output drive circuits 10. In FIG. 1, these output drive circuits 10 are respectively denoted by DRV[0], DRV[1], . . . , DRV[n-1].

### Output Drive Circuit

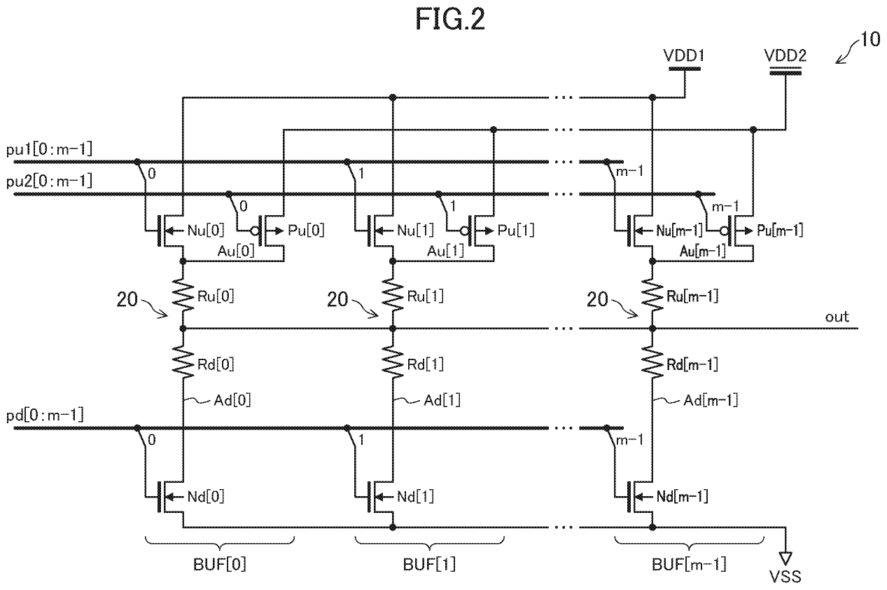

FIG. 2 is a circuit diagram showing an example of the configuration of the output drive circuit 10 according to this embodiment.

As shown in FIG. 2, the output drive circuit 10 includes a plurality of output buffers 20. The plurality of output buffers 20 are provided in parallel between power supply nodes VDD1 and VDD2 and a ground node VSS. The output drive circuit 10 of FIG. 2 includes m (m: natural number) output buffers 20.

Each of the output buffers 20 has a push-pull structure including a pullup transistor and a pulldown transistor, for example.

Specifically, the output buffer 20 includes a p-type pullup transistor Pu, an n-type pullup transistor Nu, a pullup resistor Ru, a pulldown resistor Rd, and an n-type pulldown transistor Nd.

In this embodiment, the p-type corresponds to the “first conductivity type” and the n-type to the “second conductivity type.” The pullup transistor Pu corresponds to the “first transistor,” the pullup transistor Nu to the “second transistor,” and the pulldown transistor Nd to the “third transistor.” The pullup resistor Ru corresponds to the “first resistor” and the pulldown resistor Rd to the “second resistor.”

The pullup transistor Pu is provided between the power supply node VDD2 (corresponding to the “first power supply node”) and a node Au (corresponding to the first node) and has a gate connected to a control line pu2. The pullup transistor Nu is provided between the power supply node VDD1 (corresponding to the “second power supply node”) and the node Au and has a gate connected to a control line pu1. The pullup resistor Ru is provided between the node Au and the output node out. Note that, in the present disclosure, the term “connection” is a concept widely covering any electrical connection between components, including, not only the case that components are connected directly, but also the case that components are electrically connected indirectly via a passive element, etc.

To state differently, the pullup transistor Pu and the pullup resistor Ru are provided in series between the power supply node VDD2 and the output node out. Also, the pullup transistor Nu and the pullup resistor Ru are provided in series between the power supply node VDD1 and the output node out. That is, the pullup transistor Pu and the pullup transistor Nu share the pullup resistor Ru.

The pulldown transistor Nd is provided between the ground node VSS (corresponding to the “third power supply node”) and a node Ad (corresponding to the second node) and has a gate connected to a control line pd. The pulldown resistor Rd is provided between the node Ad and the output node out. In other words, the pulldown transistor Nd and the pulldown resistor Rd are provided in series between the ground node VSS and the output node out.

Note here that the voltage of the power supply node VDD1 is equal to or lower than the voltage of the power supply node VDD2. That is, VDD1≤VDD2. The voltage of the ground node VSS is lower than the voltage of the power supply node VDD1 and also lower than the voltage of the power supply node VDD2.

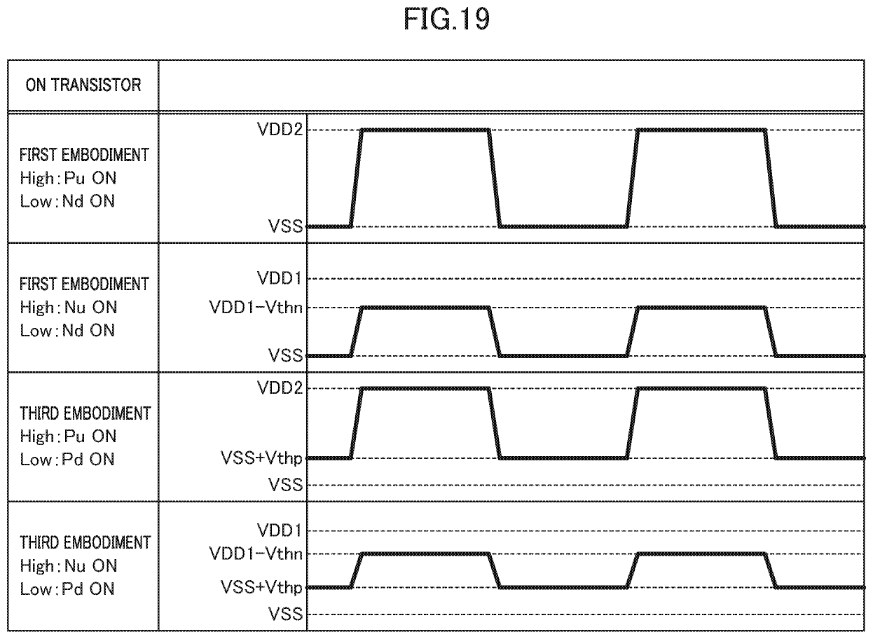

In the pullup transistor Pu, the power supply node VDD2 is connected to the source. Therefore, when the pullup transistor Pu is turned ON, it has a gate-source voltage (Vgs) of “Vgs=VDD2” thereby operating stably. Also, a signal having a full amplitude from the power supply voltage VDD2 to the reference voltage (ground) is output from the output terminal OUT (see the waveform in the first row in FIG. 19).

In the pullup transistor Nu, the power supply node VDD1 is connected to the drain. Therefore, when the pullup transistor Nu is ON, the voltage of the output signal out output from the output terminal OUT is “VDD1−Vthn” (Vthn: threshold of NMOS) (see the waveform in the second row in FIG. 19).

As described above, since VDD1≤VDD2 is set, a low-voltage and small-amplitude signal is output when the pullup transistor Nu is turned ON in comparison with when the pullup transistor Pu is turned ON. A small-amplitude signal is effective in high-speed output short in cycle time, for example.

Note that the output impedance value of the output drive circuit 10 is not specifically limited, but is determined based on the specifications of the external interface connected to the output terminal OUT and from the standpoint of the area efficiency of the output circuit 1. At this time, in order to comply with a variety of output impedance standards, the output impedance value of each output drive circuit 10 may be designed large. Also, some or all of the plurality of output drive circuits 10 may have a common impedance value, or the output drive circuits 10 may have impedance values different from one another. This also applies to the output impedance values of output drive circuits 10 according to other embodiments described later.

Note that in FIG. 2, the output buffers 20 are individually denoted by BUF[0], BUF[1], . . . , BUF[m-1], and the components included in the respective BUF[0:m-1] and the control lines connected to these components are denoted in a similar manner. Specifically, as for the components included in BUF[0], the pullup transistor Pu is denoted by Pu[0], the pullup transistor Nu by Nu[0], the pullup resistor Ru by Ru[0], the pulldown transistor Nd by Nd[0], and the pulldown resistor Rd by Rd[0]. The control line pu2[0] is connected to the gate of the pullup transistor Pu[0], the control line pu1[0] is connected to the gate of the pullup transistor Nu[0], and the control line pd[0] is connected to the gate of the pulldown transistor Nd[0]. This also applies to BUF[1], ..., BUF[m-1].

Referring back to FIG. 1, the output circuit 1 also has selection terminals MSELU, CDRV[0:n-1], CBUFU[0:m-1], and CBUFD[0:m-1] and an enable control terminal OEN, in addition to the input terminal IN and the output terminal OUT.

### Output Control Circuit

The output control circuit 30 outputs control signals pu1[0:m-1], pu2[0:m-1], and pd[0:m-1] to each of the output drive circuits 10 (DRV[0:n-1]). With the control signals pu2[0:m-1], the activation/deactivation of the pullup transistors Pu[0:m-1] of the output buffers 20 (BUF[0:m-1]) is controlled. Similarly, with the control signals pu1[0:m-1], the activation/deactivation of the pullup transistors Nu[0:m-1] is controlled, and with the control signals pd[0:m-1], the activation/deactivation of the pulldown transistors Nd[0:m-1] is controlled.

To state more specifically, for example, with the control signal pu2[0], the activation/deactivation of the pullup transistor Pu[0] of the output buffer 20 (BUF[0]) is controlled. With the control signal pu1[0], the activation/deactivation of the pullup transistor Nu[0] of the output buffer 20 (BUF[0]) is controlled. With the control signal pd[0], the activation/deactivation of the pulldown transistor Nd[0] of the output buffer 20 (BUF[0]) is controlled. This also applies to the control of activation/deactivation in the output buffers 20 (BUF[1:m-1]). The control signals pu1[0:m-1] and pu2[0:m-1] correspond to the first control signal.

The input signal in is input into the output control circuit 30 through the input terminal IN. Selection signals mselu, cdrv[0:n-1], cbufu[0:m-1], and cbufd[0:m-1] and an enable control signal oen are input into the output control circuit 30 through the selection terminals MSELU, CDRV, CBUFU, and CBUFD and the enable control terminal OEN, respectively.

The selection terminal MSELU is a selection terminal for pullup transistors: the pullup transistors Pu or the pullup transistors Nu in all the output drive circuits 10 are selected collectively with the selection signal mselu. For example, with “mselu=1,” the pullup transistors Pu are selected in all the output drive circuits 10, and with “mselu=0,” the pullup transistors Nu are selected in all the output drive circuits 10.

The selection terminals CDRV[0:n-1] are selection terminals for the output drive circuits 10: with the selection signals cdrv[0:n-1], the activation/deactivation of the output drive circuits 10 corresponding to the respective selection signals cdrv[0:n-1] is selected. For example, with “cdrv[0]=1,” the output drive circuit 10 (DRV[0]) is activated, and with “cdrv[0]=0,” the output drive circuit 10 (DRV[0]) is deactivated. Similarly, with the selection signals cdrv[1:n-1], the activation/deactivation of the output drive circuits 10 (DRV[1:n-1]) is selected. The number of output drive circuits 10 to be activated is determined depending on the external interface specifications at the output terminal OUT. For example, assume that each output drive circuit 10 is designed to have an output impedance of 150 [Ω] uniformly. In this case, to respond to the external interface specifications having an output impedance standard of 30 [Ω], the number of output drive circuits 10 to be driven will be 150 [Ω]÷30 [Ω]=5. The selection signals cdrv[0:n-1] correspond to the second control signal.

The selection terminals CBUFU[0:m-1] are selection terminals for drive transistors (pullup side): with the selection signals cbufu[0:m-1], in the output drive circuit 10 corresponding to each of the selection signals cdrv[0:n-1], the activation/deactivation of the pullup transistor (the pullup transistor Pu or the pullup transistor Nu) selected by the selection signal mselu is selected. For example, when “mselu=1” and “cbufu[0]=1,” the pullup transistor Pu of the output buffer 20 (BUF[0]) is activated. When “mselu=1” and “cbufu[0]=0,” the pullup transistor Pu of the output buffer 20 (BUF[0]) is deactivated. Also, for example, when “mselu=0” and “cbufu[0]=1,” the pullup transistor Nu of the output buffer 20 (BUF[0]) is activated. When “mselu=0” and “cbufu[0]=0,” the pullup transistor Nu of the output buffer 20 (BUF[0]) is deactivated. Similarly, with the selection signals cbufu[1:m-1], the activation/deactivation of the pullup transistors (pullup transistors Pu or pullup transistors Nu) is selected in the output buffers 20 (BUF[1:n-1]).

The selection terminals CBUFD[0:m-1] are selection terminals for drive transistors (pulldown side): with the selection signals cbufd[0:m-1], the activation/deactivation of the pulldown transistors is selected. For example, when “cbufd[0]=1,” the pulldown transistor Nd of the output buffer 20 (BUF[0]) is activated. When “cbufd[0]=0,” the pulldown transistor Nd of the output buffer 20 (BUF[0]) is deactivated. Similarly, with the selection signals cbufd[1:m-1], the activation/deactivation of the pulldown transistors Nd of the designated output buffers 20 (BUF[1:m-1]) is selected.

The selection signals cbufu[0:m-1] and cbufd[0:m-1] correspond to the third control signal.

The number of transistors (pullup transistors (Pu or Nu) and pulldown transistors Nd) to b activated with the selection signals cbufu[0:m-1] and the selection signals cbufd[0:m-1] is determined so as to agree with the output impedance standard in the specifications of the external interface connected to the output terminal OUT. The impedance of the output buffers 20 may be affected by manufacturing variations of elements and fluctuations of the ambient temperature and power supply voltages. Therefore, when the tolerance of the output impedance standard is defined, for example, it is necessary to adjust the number of transistors to be activated described above appropriately according to this definition.

Note that the selection signals cbufu[0:m-1] and the selection signals cbufd[0:m-1] are generated by a logic circuit (not shown) inside the LSI, for example. In particular, when high output impedance precision is required, the configuration may be made to perform fine adjustment of the impedance using a calibration circuit (not shown).

The activation/deactivation of all the output drive circuits 10 is selected with the enable control signal oen. For example, with “oen=1,” all the output drive circuits 10 (DRV[0:n-1]) are activated, and with “oen=0,” all the output drive circuits 10 (DRV[0:n-1]) are deactivated. In other words, when the enable (hereinafter also expressed as “activated”) state is set with the enable control signal oen, i.e., when “oen=1” is set, the input signal in input into the input terminal IN is output to the output terminal OUT as the output signal out. On the other hand, when the disable (hereinafter also expressed as “deactivated”) state is set with the enable control signal oen, i.e., when “oen=0” is set, the output signal out becomes a floating (high impedance) state irrespective of the state of the input signal in.

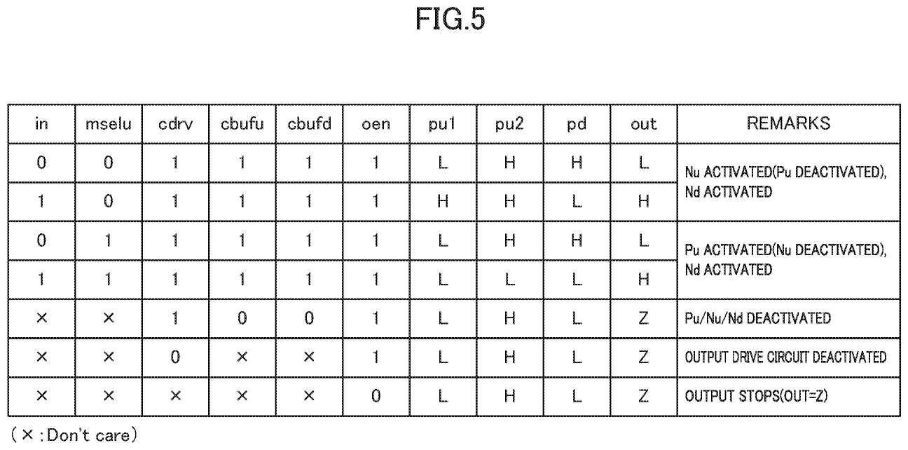

FIG. 5 shows an example of a truth table indicating the relationship among the inputs (the input signal in, the selection signals mselu, cdrv, cbufu[0:m-1], and cbufd[0:m-1], and the enable control signal oen) and the outputs (the control signals pu1[0:m-1], pu2[0:m-1], and pd[0:m-1]) of the output control circuit 30, and the output signal out.

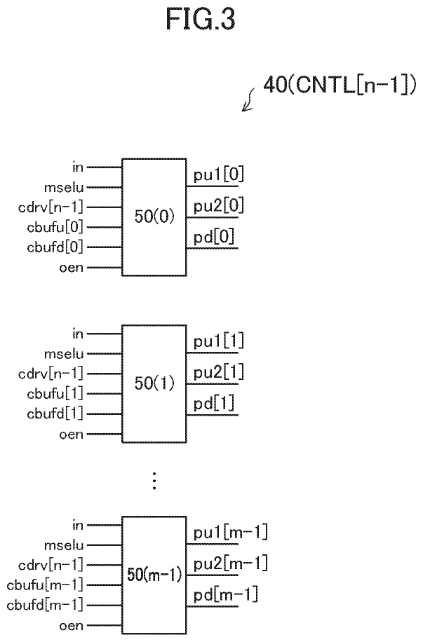

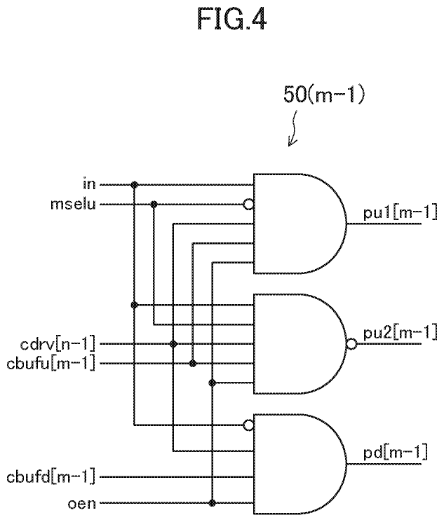

The output control circuit 30 includes data processing parts 40 and 50 that implement the logical function of the truth table of FIG. 5. FIGS. 3 and 4 show a configuration example of logic circuits that implement the logical function of the truth table of FIG. 5. Note however that the configuration of the output control circuit 30 is not limited to the configuration example shown in FIGS. 3 and 4, but any other circuit configuration having an equivalent logical function may be used. Also, part of the function of the data processing parts 40 and 50 may be implemented by a program incorporated in a microcontroller (not shown) and the like. This also applies to the other embodiments described later.

### Effects of First Embodiment

In this embodiment, in each of the output drive circuits 10, the pullup transistors Pu and Nu of different conductivity types are included in a mixed manner. Therefore, in comparison with the case of constituting output drive circuits 10 corresponding to the pullup transistors Pu and the pullup transistors Nu separately, the number of units of the output drive circuits 10 can be reduced. With the reduction in the number of units, the occupied area of the output circuit 1 can be reduced.

In this embodiment, the pullup transistors Pu and Nu share the pullup resistor Ru. Therefore, in comparison with the case of using separate pullup resistors Ru for the pullup transistor Pu and the pullup transistor Nu, the number of resistive elements used can be reduced, and this can reduce the occupied area of the output circuit 1. In the output circuit 1, the resistance value of the pullup resistor Ru tends to be designed large compared with the ON resistance of the transistor from the standpoint of maintaining the linearity of the output impedance characteristics. Therefore, as the impedance value per unit of the output drive circuits 10 becomes larger, the occupied area of the resistive element used will be larger. In such a case, the effect of this embodiment will be exhibited more significantly.

Moreover, with the reduction in the area of placement of resistive elements, the parasitic capacitance to the output node out and the output terminal OUT is reduced, and this speeds up the transition (slew rate) of the output signal. That is, a waveform excellent in the openings of the so-called eye pattern (eye diagram), formed by overlaying sampling waveforms, is obtained, and this permits output of a high-speed signal short in cycle time.

In this embodiment, in each of the output drive circuits 10, the pullup transistors Pu and Nu of different conductivity types are operated selectively. With this, a full-amplitude output signal out and a small-amplitude output signal out can be generated: i.e., these output signals can be used selectively. The small-amplitude output signal is effective in outputting a high-speed signal. Moreover, in this embodiment, the voltages of the power supplies VDD1 and VDD2 are made different from each other, to offer additional variations. In this way, the output signal out conforming to a wide variety of external interface specifications can be output.

### Second Embodiment

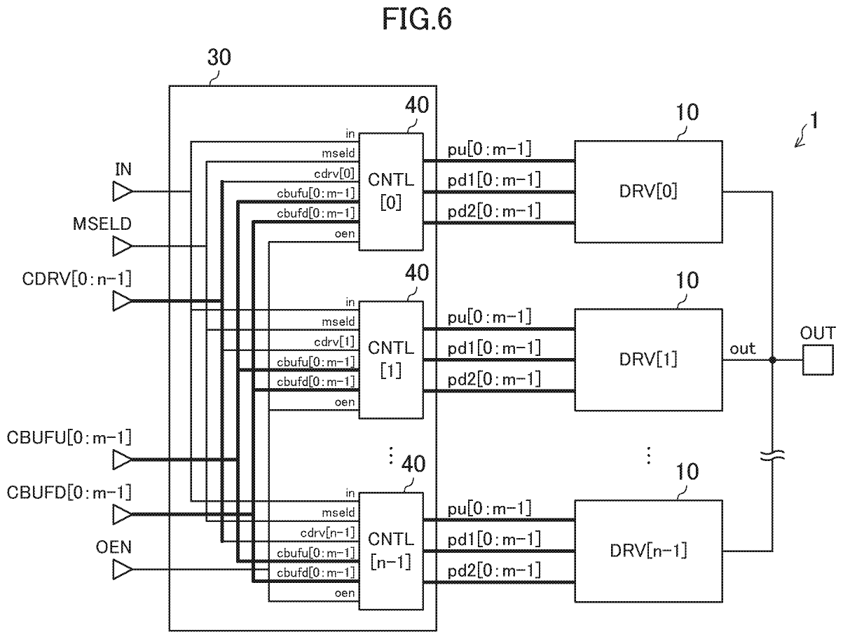

FIG. 6 shows an example of the circuit diagram of an output circuit 1 according to the second embodiment. In FIG. 6, components corresponding to those in FIG. 1 are denoted by the same reference characters. The following description will be made centering on differences from the first embodiment. Note that elements (e.g., transistors and resistors) denoted by the same reference characters in FIGS. 1 and 6 are not intended to be the same in various design parameters, process parameters, and the like. That is, configurations in which elements denoted by the same reference characters in FIGS. 1 and 6 have parameters different from each other also fall within the technical scope of the present disclosure. This also applies to the relationships between other drawings.

The output circuit 1 of this embodiment is different from that of the first embodiment in the configuration of the output drive circuits 10. Also, along with this difference, the control signals input into the output drive circuits 10 and the configuration of the output control circuit 30 are different from those in the first embodiment.

### Output Drive Circuit

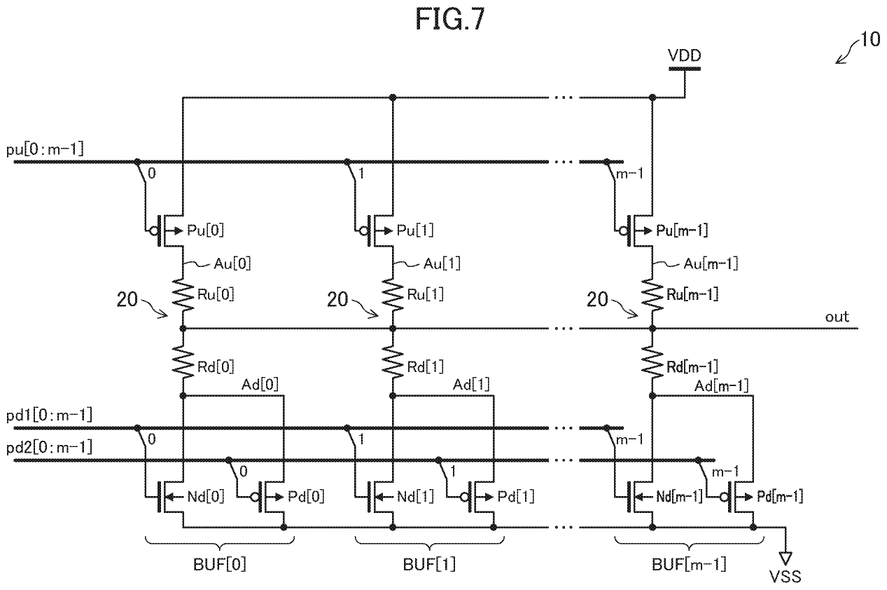

FIG. 7 is a circuit diagram showing an example of the configuration of the output drive circuit 10 according to this embodiment. As in the first embodiment, the output drive circuit 10 includes a plurality of output buffers 20.

In this embodiment, each of the output buffers 20 includes: a p-type pullup transistor Pu a the pullup transistor; and an n-type pulldown transistor Nd and a p-type pulldown transistor Pd as the pulldown transistor. Also, as in the first embodiment, a pullup resistor Ru and a pulldown resistor Rd are provided.

In this embodiment, the n-type corresponds to the “first conductivity type” and the p-type to the “second conductivity type.” The pulldown transistor Nd corresponds to the “first transistor,” the pulldown transistor Pd to the “second transistor,” and the pullup transistor Pu to the “third transistor.” The pulldown resistor Rd corresponds to the “first resistor” and the pullup resistor Ru to the “second resistor.”

Specifically, the pullup transistor Pu is provided between a power supply node VDD (corresponding to the “third power supply node”) and a node Au (corresponding to the second node) and has a gate connected to a control line pu. The pullup resistor Ru is provided between the node Au and the output node out. In other words, the pullup transistor Pu and the pullup resistor Ru are provided in series between the power supply node VDD and the output node out.

The pulldown transistor Nd is provided between a ground node VSS (corresponding to the “first power supply node”) and a node Ad (corresponding to the first node) and has a gate connected to a control line pd1. The pulldown transistor Pd is provided between the ground node VSS (corresponding to the “second power supply node”) and the node Ad and has a gate connected to a control line pd2. The pulldown resistor Rd is provided between the node Ad and the output node out.

In other words, the pulldown transistor Nd and the pulldown resistor Rd are provided in series between the ground node VSS and the output node out. Also, the pulldown transistor Pd and the pulldown resistor Rd are provided in series between the ground node VSS and the output node out. That is, the pulldown transistor Nd and the pulldown transistor Pd share the pulldown resistor Rd.

Note here that the voltage of the power supply node VDD is higher than the voltage of the ground node VSS. That is, VDD>VSS.

In the pulldown transistor Nd, the ground node VSS is connected to the source. Therefore, when the pulldown transistor Nd is turned ON, a full-amplitude signal is output from the output terminal OUT.

In the pulldown transistor Pd, the ground node VSS is connected to the drain. Therefore, when the pulldown transistor Pd is ON, the voltage of the output signal out output from the output terminal OUT is “VSS+Vthp” (Vthp: threshold of PMOS).

As described above, when the pulldown transistor Pd is turned ON, a low-voltage and small-amplitude signal is output in comparison with when the pulldown transistor Nd is turned ON. A small-amplitude signal is effective in high-speed output short in cycle time, for example.

Note that in FIG. 7, as in FIG. 2, the output buffers 20 are individually denoted by BUF[0], BUF[1], . . . , BUF[m-1], and the components included in the respective BUF[0:m-1] and the control lines connected to these components are denoted in a similar manner.

### Output Control Circuit

As shown in FIG. 6, the output control circuit 30 outputs control signals pu[0:m-1], pd1[0:m-1], and pd2[0:m-1] to each of the output drive circuits 10 (DRV[0:n-1]).

As shown in FIG. 7, with the control signals pu[0:m-1], the activation/deactivation of the pullup transistors Pu[0:m-1] of the output buffers 20 (BUF[0:m-1]) is controlled. Similarly, with the control signals pd1[0:m-1], the activation/deactivation of the pulldown transistors Nd[0:m-1] is controlled, and with the control signals pd2[0:m-1], the activation/deactivation of the pulldown transistors Pd[0:m-1] is controlled.

Referring back to FIG. 6, as in the first embodiment, the input signal in is input into the output control circuit 30 through the input terminal IN. Selection signals mseld, cdrv[0:n-1], cbufu[0:m-1], and cbufd[0:m-1] and an enable control signal oen are input into the output control circuit 30 through the selection terminals MSELD, CDRV, CBUFU, and CBUFD and the enable control terminal OEN, respectively.

The selection terminal MSELD is a selection terminal for pulldown transistors: the pulldown transistors Nd or the pullup transistors Pd in all the output drive circuits 10 are selected collectively with the selection signal mseld. For example, with “mseld=1,” the pulldown transistors Nd are selected in all the output drive circuits 10, and with “mseld=0,” the pulldown transistors Pd are selected in all the output drive circuits 10.

The selection terminals CDRV, CBUFU, and CBUFD and the enable control terminal OEN, and the selection signals cdrv[0:n-1], cbufu[0:m-1], and cbufd[0:m-1] and the enable control signal oen are similar to those in the first embodiment, and therefore detailed description thereof is omitted here.

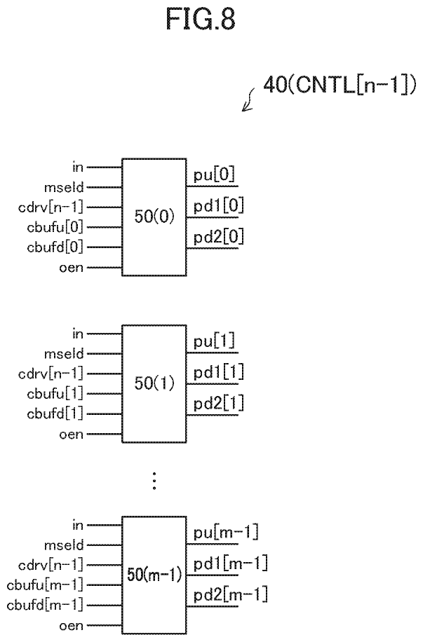

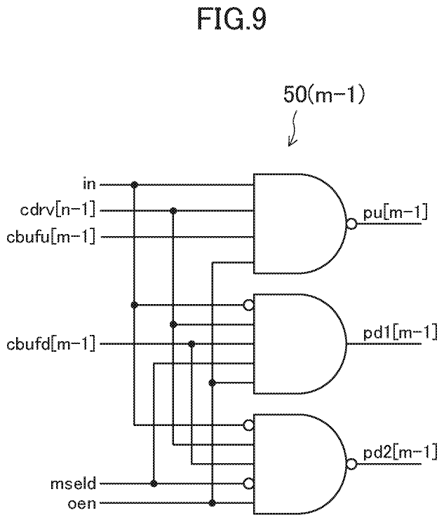

The output control circuit 30 includes data processing parts 40 and 50 that implement the logical function of a truth table equivalent to FIG. 5. FIGS. 8 and 9 show a configuration example of logic circuits that implement the logical function of the truth table equivalent to FIG. 5. Note however that the configuration is not limited to the configuration example shown in FIGS. 8 and 9, but any other circuit configuration having an equivalent logical function may be used.

### Effects of Second Embodiment

In this embodiment, also, similar effects to those in the first embodiment are obtained.

Specifically, in comparison with the case of constituting output drive circuits 10 corresponding to the pulldown transistors Nd and Pd individually, the number of units of the output drive circuits 10 can be reduced. With the reduction in the number of units, the occupied area of the output circuit 1 can be reduced.

Since the pulldown transistors Nd and Pd share the pulldown resistor Rd, the number of resistive elements used can be reduced, and this can reduce the occupied area of the output circuit 1. Also, the transition (slew rate) of the output signal out is sped up, and this permits output of a high-speed signal short in cycle time.

Since the pulldown transistors Nd and Pd of different conductivity types are operated selectively, a small-amplitude output signal out can be generated. Also, the output signal out conforming to a wide variety of external interface specifications can be output.

### Third Embodiment

This embodiment is different from the first embodiment in that each output buffer 20 has p-type pulldown transistor Pd as the pulldown transistor. The other configuration of this embodiment (e.g., the configurations of the pullup transistors (Nu and Pu), the pullup resistor Ru, and the pulldown resistor Rd of the output buffer 20 and the output control circuit 30) is similar to that of the first embodiment.

### Output Drive Circuit

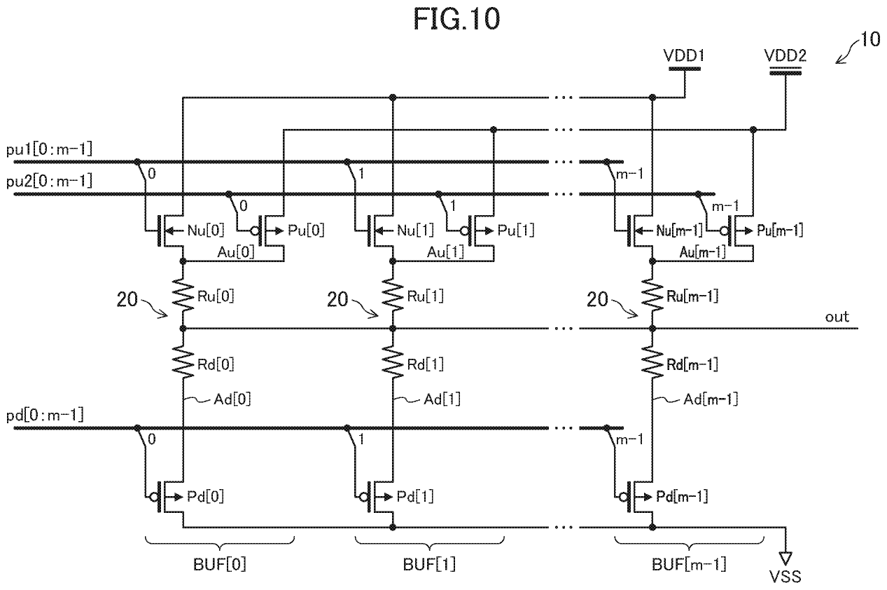

FIG. 10 shows an example of the configuration of the output drive circuit 10 according to this embodiment. As in the first embodiment, the output drive circuit 10 includes a plurality of output buffers 20.

As described above, each of the output buffers 20 has a p-type pulldown transistor Pd as the pulldown transistor. That is, the output buffer 20 includes the p-type pullup transistor Pu, the n-type pullup transistor Nu, the pullup resistor Ru, the pulldown resistor Rd, and the p-type pulldown transistor Pd.

In this embodiment, the n-type corresponds to the “first conductivity type” and the p-type to the “second conductivity type.” The pullup transistor Nu corresponds to the “first transistor,” the pullup transistor Pu to the “second transistor,” and the pulldown transistor Pd to the “third transistor.” The pullup resistor Ru corresponds to the “first resistor” and the pulldown resistor Rd to the “second resistor.” The power supply node VDD1 corresponds to the first power supply node, and the power supply node VDD2 corresponds to the second power supply node.

Note here that the voltage of the power supply node VDD1 is equal to or lower than the voltage of the power supply node VDD2. That is, VDD1≤VDD2. The voltage of the ground node VSS is lower than the voltage of the power supply node VDD1 and also lower than the voltage of the power supply node VDD2.

In this embodiment, when the pulldown transistor Pd is ON, i.e., when “control signal pd=0,” the drain voltage of the pulldown transistor Pd, i.e., the LOW output voltage of the output node out is out=VSS+Vthp. Therefore, a small-amplitude signal is output. Specifically, when the pullup transistor Nu is selected and the pulldown transistor Pd is ON, for example, the waveform in the first row from bottom in FIG. 19 is output. Also, when the pullup transistor Pu is selected and the pulldown transistor Pd is ON, the waveform in the second row from bottom in FIG. 19 is output.

### Effects of Third Embodiment

In this embodiment, also, similar effects to those in the first embodiment are obtained.

Specifically, in comparison with the case of constituting output drive circuits 10 corresponding to the pullup transistors Nu and Pu individually, the number of units of the output drive circuits 10 can be reduced. With the reduction in the number of units, the occupied area of the output circuit 1 can be reduced.

Since the pullup transistors Nu and Pu share the pullup resistor Ru, the number of resistive elements used can be reduced, and this can reduce the occupied area of the output circuit 1. Also, with the reduction in the area of placement of resistive elements, the parasitic capacitance to the output node out and the output terminal OUT is reduced. This speeds up the transition (slew rate) of the output signal out, permitting output of a high-speed signal short in cycle time.

Since the pullup transistors Nu and Pu of different conductivity types are operated selectively, a small-amplitude output signal out can be generated. Also, the output signal out conforming to a wide variety of external interface specifications can be output.

### Fourth Embodiment

This embodiment is different from the second embodiment in that each output buffer 20 has an n-type pullup transistor Nu as the pullup transistor. The other configuration of this embodiment (e.g., the configurations of the pulldown transistors (Nd and Pd), the pullup resistor Ru, and the pulldown resistor Rd of the output buffer 20 and the output control circuit 30) is similar to that of the second embodiment.

### Output Drive Circuit

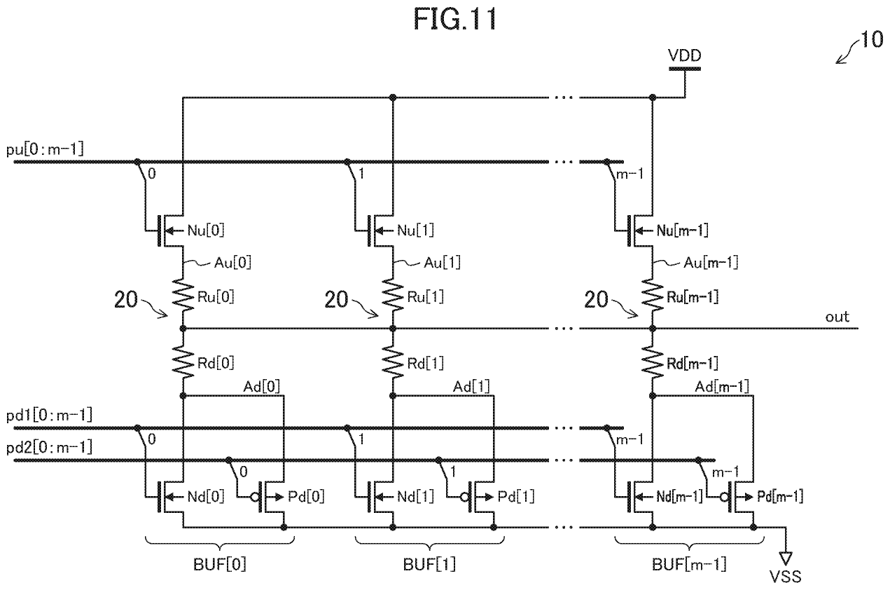

FIG. 11 shows an example of the configuration of the output drive circuit 10 according to this embodiment. As in the second embodiment, the output drive circuit 10 includes a plurality of output buffers 20.

As described above, each of the output buffers 20 has an n-type pullup transistor Nu as the pullup transistor. That is, the output buffer 20 includes the n-type pullup transistor Nu, the pullup resistor Ru, the pulldown resistor Rd, the p-type pulldown transistor Pd, and the n-type pulldown transistor Nd.

In this embodiment, the p-type corresponds to the “first conductivity type” and the n-type to the “second conductivity type.” The pulldown transistor Pd corresponds to the “first transistor,” the pulldown transistor Nd to the “second transistor,” and the pullup transistor Nu to the “third transistor.” The pulldown resistor Rd corresponds to the “first resistor” and the pullup resistor Ru to the “second resistor.” The ground node VSS corresponds to the first power supply node and the second power supply node, and the power supply node VDD corresponds to the third power supply node.

Note here that the voltage of the power supply node VDD is higher than the voltage of the ground node VSS. That is, VDD>VSS.

In this embodiment, when the pullup transistor Nu is ON, i.e., when “control signal pu=1,” the drain voltage of the pullup transistor Nu, i.e., the HIGH output voltage of the output node out is out=VDD−Vthn (Vthn: threshold of NMOS). Therefore, a small-amplitude signal is output.

### Effects of Fourth Embodiment

In this embodiment, also, similar effects to those in the first embodiment are obtained.

Specifically, in comparison with the case of constituting output drive circuits 10 corresponding to the pulldown transistors Nd and Pd individually, the number of units of the output drive circuits 10 can be reduced. With the reduction in the number of units, the occupied area of the output circuit 1 can be reduced.

Since the pulldown transistors Nd and Pd share the pulldown resistor Rd, the number of resistive elements used can be reduced, and this can reduce the occupied area of the output circuit 1. Also, with the reduction in the area of placement of resistive elements, the parasitic capacitance to the output node out and the output terminal OUT is reduced. This speeds up the transition (slew rate) of the output signal out, permitting output of a high-speed signal short in cycle time.

Since the pulldown transistors Nd and Pd of different conductivity types are operated selectively, a small-amplitude output signal out can be generated. Also, the output signal out conforming to a wide variety of external interface specifications can be output.

### Fifth Embodiment

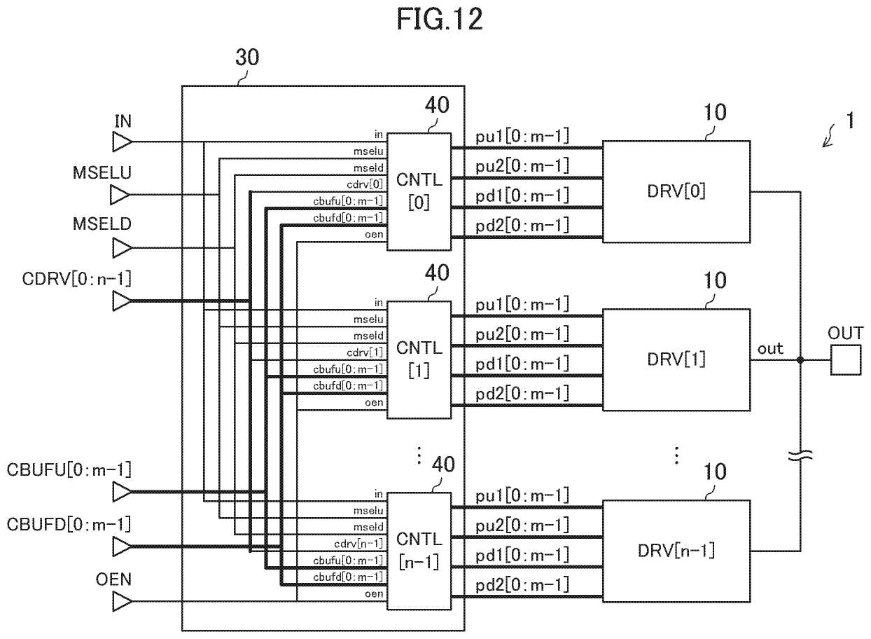

FIG. 12 is a circuit diagram showing an example of the configuration of an output circuit according to this embodiment. As in the first embodiment, the output circuit 1 has a plurality of output drive circuits 10. In FIG. 12, components corresponding to those in FIG. 1 are denoted by the same reference characters. The following description will be made centering on differences from the first embodiment.

The output circuit 1 of this embodiment is different from that of the first embodiment in the configuration of the output drive circuits 10. Also, along with this difference, the control signals input into the output drive circuits 10 and the configuration of the output control circuit 30 are different from those in the first embodiment.

### Output Drive Circuit

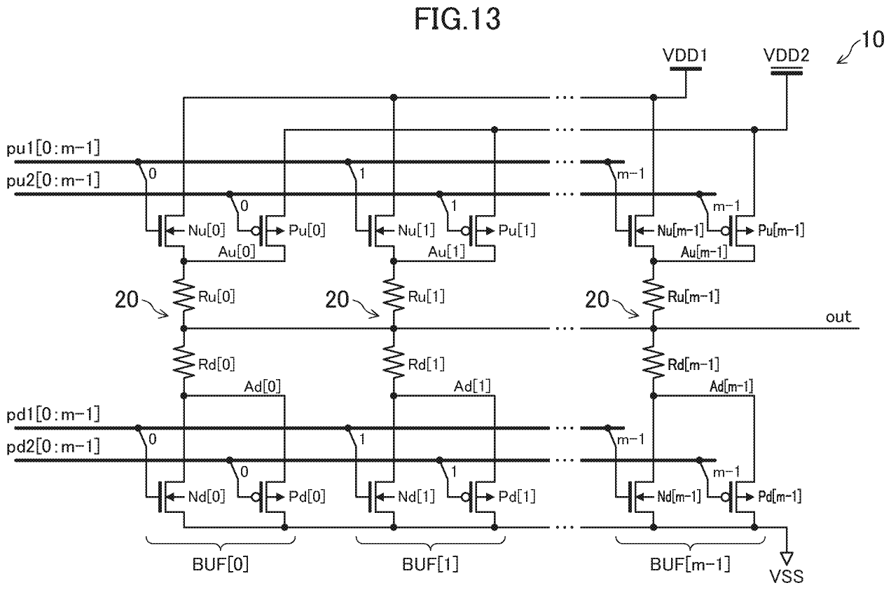

FIG. 13 is a circuit diagram showing an example of the configuration of the output drive circuit 10 according to this embodiment. As in the first embodiment, the output drive circuit 10 includes a plurality of output buffers 20.

In this embodiment, each of the output buffers 20 includes: a p-type pullup transistor Pu and an n-type pullup transistor Nu as the pullup transistor; and an n-type pulldown transistor Nd and a p-type pulldown transistor Pd as the pulldown transistor. Also, as in the first embodiment, a pullup resistor Ru and a pulldown resistor Rd are provided. That is, this embodiment is different from the first embodiment in that the output buffer 20 includes the p-type pulldown transistor Pd in addition to the n-type pulldown transistor Nd as the pulldown transistor.

Specifically, the pulldown transistor Nd is provided between a ground node VSS (corresponding to the “third power supply node”) and a node Ad (corresponding to the second node) and has a gate connected to a control line pd1. The pulldown transistor Pd is provided between the ground node VSS and the node Ad and has a gate connected to a control line pd2. The pulldown resistor Rd is provided between the node Ad and the output node out.

In this embodiment, the p-type corresponds to the “first conductivity type” and the n-type to the “second conductivity type.” The pullup transistor Pu corresponds to the “first transistor,” the pullup transistor Nu to the “second transistor,” the pulldown transistor Pd to the “fourth transistor,” and the pulldown transistor Nd to the “third transistor.” The pullup resistor Ru corresponds to the “first resistor” and the pulldown resistor Rd to the “second resistor.”

Note here that, as in the first embodiment, the voltage of the power supply node VDD1 is equal to or lower than the voltage of the power supply node VDD2. That is, VDD1≤VDD2. The voltage of the ground node VSS is lower than the voltage of the power supply node VDD1 and also lower than the voltage of the power supply node VDD2. Therefore, a low-voltage and small-amplitude signal is output when the pullup transistor Nu is turned ON, in comparison with when the pullup transistor Pu is turned ON. A small-amplitude signal is effective in high-speed output short in cycle time.

Also, as in the second embodiment, in the pulldown transistor Nd, the ground node VSS is connected to the source. Therefore, when the pulldown transistor Nd is turned ON, a full-amplitude signal is output from the output terminal OUT. In the pulldown transistor Pd, the ground node VSS is connected to the drain. Therefore, when the pulldown transistor Pd is ON, the voltage of the output signal out output from the output terminal OUT is “VSS+Vthp” (Vthp: threshold of PMOS). A small-amplitude signal is therefore output from the output terminal OUT.

### Output Control Circuit

Referring back to FIG. 12, the output control circuit 30 outputs control signals pu1[0:m-1], pu2[0:m-1], pd1[0:m-1], and pd2[0:m-1] to each of the output drive circuits 10 (DRV[0:n-1]). With the control signals pu1[0:m-1], the activation/deactivation of the pullup transistors Nu[0:m-1] of the output buffers 20 (BUF[0:m-1]) is controlled. Similarly, with the control signals pu2[0:m-1], the activation/deactivation of the pullup transistors Pu[0:m-1] of the output buffers 20 (BUF[0:m-1]) is controlled. With the control signals pd1[0:m-1], the activation/deactivation of the pulldown transistors Nd[0:m-1] is controlled, and with the control signals pd2[0:m-1], the activation/deactivation of the pulldown transistors Pd[0:m-1] is controlled.

As in the first embodiment, the input signal in is input into the output control circuit 30 through the input terminal IN. Selection signals mselu, mseld, cdrv[0:n-1], cbufu[0:m-1], and cbufd[0:m-1] and an enable control signal oen are input into the output control circuit 30 through selection terminals MSELU, MSELD, CDRV, CBUFU, and CBUFD and an enable control terminal OEN, respectively.

As in the second embodiment, the selection terminal MSELD is a selection terminal for pulldown transistors: the pulldown transistors Nd or the pulldown transistors Pd in all the output drive circuits 10 are selected collectively with the selection signal mseld. For example, with “mseld=1,” the pulldown transistors Nd are selected in all the output drive circuits 10, and with “mseld=0,” the pulldown transistors Pd are selected in all the output drive circuits 10.

The selection terminals MSELU, CDRV, CBUFU, and CBUFD and the enable control terminal OEN, and the selection signals mselu, cdrv[0:n-1], cbufu[0:m-1], and cbufd[0:m-1] and the enable control signal oen are similar to those in the first embodiment, and therefore detailed description thereof is omitted here.

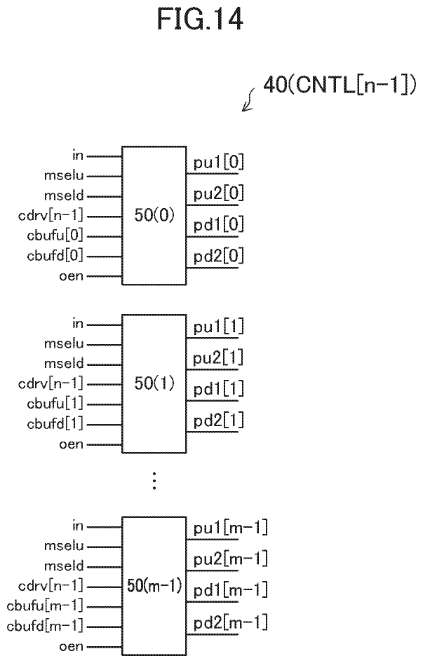

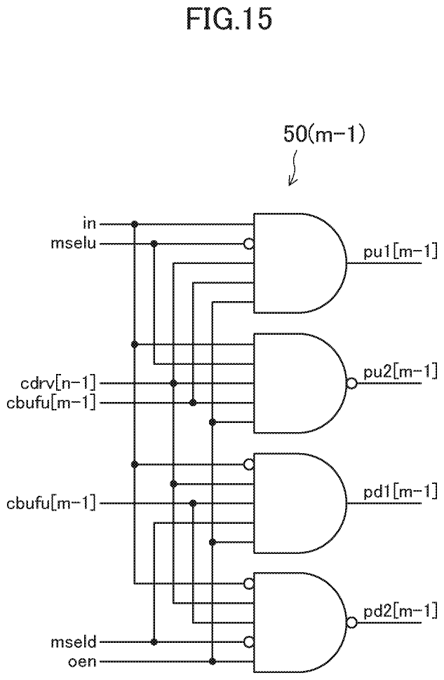

The output control circuit 30 includes data processing parts 40 and 50 that implement the logical function of a truth table equivalent to FIG. 5. FIGS. 14 and 15 show a configuration example of logic circuits that implement the logical function of the truth table equivalent to FIG. 5. Note however that the configuration is not limited to the configuration example shown in FIGS. 14 and 15, but any other circuit configuration having an equivalent logical function may be used.

### Effects of Fifth Embodiment

In this embodiment, also, similar effects to those in the first embodiment are obtained.

Specifically, in comparison with the case of constituting output drive circuits 10 corresponding to the pullup transistors Nu and Pu and the pulldown transistors Nd and Pd individually, the number of units of the output drive circuits 10 can be reduced. With the reduction in the number of units, the occupied area of the output circuit 1 can be reduced.

Since the pullup transistors Nu and Pu share the pullup resistor Ru, the number of resistive elements used can be reduced, and this can reduce the occupied area of the output circuit 1. Similarly, since the pulldown transistors Nd and Pd share the pulldown resistor Rd, the number of resistive elements used can be reduced, and this can reduce the occupied area of the output circuit 1. Also, with the reduction in the area of placement of resistive elements, the parasitic capacitance to the output node out and the output terminal OUT is reduced. This speeds up the transition (slew rate) of the output signal out, permitting output of a high-speed signal short in cycle time.

Since the pullup transistors Nu and Pu and the pulldown transistors Nd and Pd having different conductivity types are operated selectively, a small-amplitude output signal out can be generated. Also, the output signal out conforming to a wide variety of external interface specifications can be output.

Note that the technique in the present disclosure is applicable, not only to the configurations described in the above embodiments, but also to embodiments appropriately subjected to changes, replacements, additions, and omissions from the above embodiments. Also, the components described in the above embodiments can be combined to provide a new embodiment.

### Alteration 1

While the activation/deactivation of the pullup transistors or the pulldown transistors in the output buffers 20 (BUF[0:m-1]) is selected with the selection signals cbufu[0:m-1] and cbufd[0:m-1] in the above embodiments, the configuration is not limited to this.

For example, some of the plurality of output buffers 20 may be in the operable state irrespective of the selection signals cbufu[0:m-1] and cbufd[0 m-1].

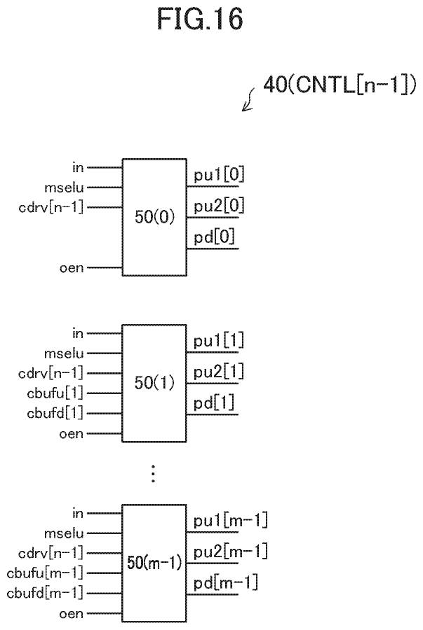

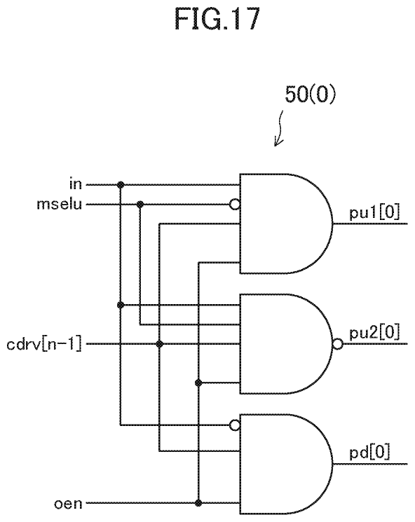

FIGS. 16 and 17 show an example of the data processing parts 40 (CNTL[n-1]) and 50(0) configured to put a specific output buffer 20 (e.g., BUF[0]) in the output drive circuit 10 (DRV[n-1]) into the operable state irrespective of the selection signals cbufu[0:m-1] and cbufd[0:m-1].

As shown in FIGS. 16 and 17, neither the selection signal cbufu[0:m-1] nor cbufd[0:m-1] is input into the data processing part 50(0). Therefore, the output buffer 20 (BUF[0]) that operates based on the output of the data processing part 50(0) becomes the operable state irrespective of the selection signals cbufu[0:m-1] and cbufd[0:m-1]. That is, BUF[0] is in the state independent of the selection signals cbufu[0:m-1] and cbufd[0:m-1].

The output control circuit 30 having the data processing parts 40 and 50 shown in FIGS. 16 and 17 is configured to output the control signals to any one of the output drive circuits 10 shown in the first to fifth embodiments.

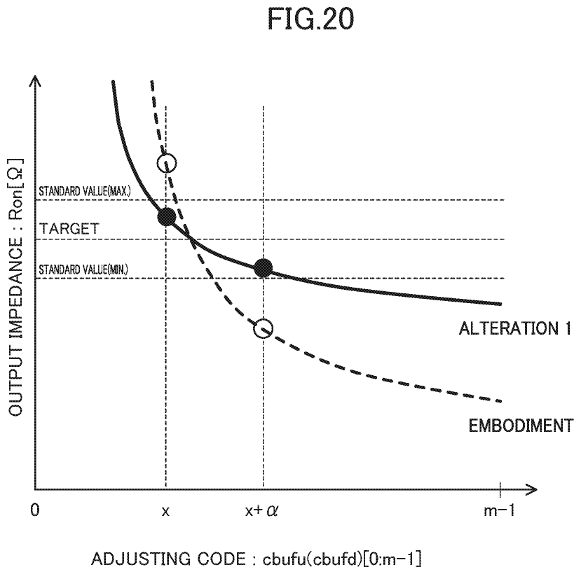

With the configuration described above, as indicated by the solid line in FIG. 20, the range of variation of the output impedance characteristics Ron (y-axis) adjusted with the code signal of the selection signals cbufu[0:m-1] or cbufd[0:m-1] (x-axis) is reduced with respect to the variation range in the other embodiments (e.g., the first embodiment) indicated by the dashed line.

### Effects of Alteration 1

By adopting the configuration of Alteration 1, the impedance variation range (ΔRon) can be reduced with respect to the output impedance characteristics in the other embodiments (e.g., the first embodiment). Therefore, even for an output impedance standard narrow in the range D of the standard value (standard value[MIN]≤D≤standard value[MAX]) like the one illustrated in FIG. 20, it becomes easy to satisfy the standard by increment/decrement adjustment of the code.

### Alteration 2

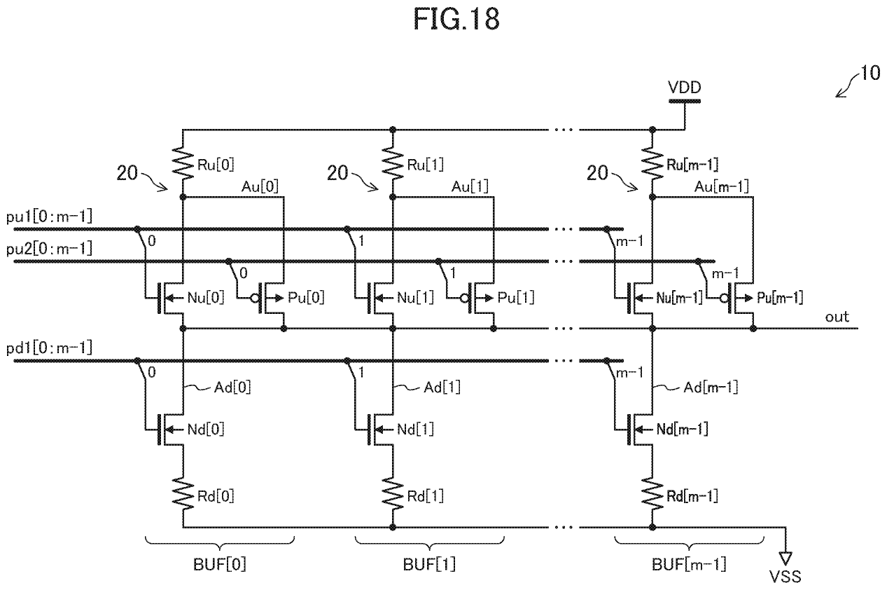

FIG. 18 shows an alteration of the output drive circuit 10 according to the first embodiment.

As shown in FIG. 18, in this alteration, the position of the pullup transistors (the pullup transistor Pu and the pullup transistor Nu) and the position of the pullup resistor Ru (corresponding to the first resistor) are interchanged. That is, the pullup resistor Ru is provided between the power supply node VDD (corresponding to the fourth power supply node) and the node Au (corresponding to the first node), and the p-type pullup transistor Pu (corresponding to the first transistor) and the n-type pullup transistor Nu (corresponding to the second transistor) are provided in parallel between the node Au and the output node out.

Also, the pulldown resistor Rd (corresponding to the second resistor) is provided between the ground node VSS (corresponding to the third node) and the node Ad (corresponding to the second node), and the n-type pulldown transistor Nd (corresponding to the third transistor) is provided between the node Ad and the output node out.

### Effects of Alteration 2

In this alteration, also, similar effects to those in the first embodiment are obtained.

Specifically, in comparison with the case of constituting output drive circuits 10 corresponding to the pullup transistors Nu and Pu individually, the number of units of the output drive circuits 10 can be reduced. With the reduction in the number of units, the occupied area of the output circuit 1 can be reduced.

Since the pullup transistors Nu and Pu share the pullup resistor Ru, the number of resistive elements used can be reduced, and this can reduce the occupied area of the output circuit 1. Also, with the reduction in the area of placement of resistive elements, the parasitic capacitance to the output node out and the output terminal OUT is reduced. This speeds up the transition (slew rate) of the output signal out, permitting output of a high-speed signal short in cycle time.

Since the pullup transistors Nu and Pu of different conductivity types are operated selectively, a small-amplitude output signal out can be generated. Also, the output signal out conforming to a wide variety of external interface specifications can be output.

Note that, while FIG. 18 is shown as an alteration of the output drive circuit 10 according to the first embodiment, it is also possible to interchange the position of the pullup resistor Ru and the position of the pullup transistor, and interchange the position of the pulldown resistor Rd and the position of the pulldown transistor, for the configurations of the output drive circuits 10 according to the second embodiment to the fifth embodiment, and similar effects are obtained.

### Other Alterations

In the above embodiments, the pullup resistor Ru and the pulldown resistor Rd have a function of imparting linearity to the impedance characteristics of the output buffer, to curb fluctuations in impedance due to manufacturing variations of transistors. In other words, when it is unnecessary to impart linearity to the output impedance characteristics, or when it is unnecessary to curb fluctuations in impedance with high precision, such as the case of using the output circuit 1 of the present disclosure for middle-or low-speed output signals, placement of the pullup resistor Ru and/or the pulldown resistor Rd is not necessarily required.

While a “single structure” in which each one of the pullup transistor Pu, the pullup transistor Nu, and the pulldown transistor Nd is provided for each of the output buffers 20 (BUF[0:m-1]) is adopted in the above embodiments, the present disclosure is not limited to this structure. For example, when transistors with a low withstanding voltage are used along with the miniaturization of transistors, a “cascode structure” (not shown) may be used in which pullup transistors Pu, pullup transistors Nu, and/or pulldown transistors Nd are each connected in series. By this structure, the voltage stress applied can be relieved.

In the above embodiments, the output control circuit 30 may be omitted. For example, the output control circuit 30 may be omitted from the output circuit 1 of FIG. 1 (the first embodiment), and the control signals pu1, pu2, and pd may be input from outside the output circuit 1. This also applies to the other embodiments.

The output circuit according to the present disclosure can respond to a variety of output characteristics, curbs the increase in area, and also permits high-speed operation. The present disclosure is therefore very useful.

1. An output circuit configured to output an output signal responsive to an input signal from an output node, comprising:
a plurality of output drive circuits connected to the output node,
wherein
each of the output drive circuits includes a plurality of output buffers,
each of the output buffers includes
a first transistor of a first conductivity type and a first resistor provided in series with each other between a first power supply node and the output node, and
a second transistor of a second conductivity type provided in series with the first resistor between a second power supply node and the output node, and
one of the first transistor and the second transistor is activated and the other is deactivated based on a first control signal.

2. The output circuit of claim 1, wherein
each of the output buffers further includes
a third transistor of the second conductivity type provided between a third power supply node and a second node, and
a second resistor provided between the second node and the output node,
the first transistor is provided between the first power supply node and a first node,
the second transistor is provided between the second power supply node and the first node, and
the first resistor is provided between the first node and the output node.

3. The output circuit of claim 2, wherein
the first conductivity type is a p-type,
the second conductivity type is an n-type,
the voltage of the third power supply node is lower than the voltage of the second power supply node, and
the voltage of the second power supply node is equal to or lower than the voltage of the first power supply node.

4. The output circuit of claim 2, wherein
the first conductivity type is an n-type,
the second conductivity type is a p-type,
the voltage of the third power supply node is higher than the voltage of the second power supply node, and
the voltage of the second power supply node is equal to the voltage of the first power supply node.

5. The output circuit of claim 2, wherein
the first conductivity type is an n-type,
the second conductivity type is a p-type,
the voltage of the third power supply node is lower than the voltage of the first power supply node, and
the voltage of the first power supply node is equal to or lower than the voltage of the second power supply node.

6. The output circuit of claim 2, wherein
the first conductivity type is a p-type,
the second conductivity type is an n-type,
the voltage of the third power supply node is higher than the voltage of the second power supply node, and
the voltage of the second power supply node is equal to the voltage of the first power supply node.

7. The output circuit of claim 1, wherein
each of the output buffers further includes
a second resistor provided between a third power supply node and a second node, and
a third transistor of the second conductivity type provided between the second node and the output node,
the first power supply node and the second power supply node are mutually connected via a fourth power supply node,
the first resistor is provided between the fourth power supply node and a first node, and
the first transistor and the second transistor are provided in parallel with each other between the first node and the output node.

8. The output circuit of claim 7, wherein
the first conductivity type is a p-type,
the second conductivity type is an n-type,
the voltage of the third power supply node is lower than the voltage of the second power supply node, and
the voltage of the second power supply node is equal to the voltage of the first power supply node.

9. The output circuit of claim 7, wherein
the first conductivity type is an n-type,
the second conductivity type is a p-type,
the voltage of the third power supply node is higher than the voltage of the second power supply node, and
the voltage of the second power supply node is equal to the voltage of the first power supply node.

10. The output circuit of claim 7, wherein
the first conductivity type is an n-type,
the second conductivity type is a p-type,
the voltage of the third power supply node is lower than the voltage of the first power supply node, and
the voltage of the first power supply node is equal to the voltage of the second power supply node.

11. The output circuit of claim 7, wherein
the first conductivity type is a p-type,
the second conductivity type is an n-type,
the voltage of the third power supply node is higher than the voltage of the second power supply node, and
the voltage of the second power supply node is equal to the voltage of the first power supply node.

12. The output circuit of claim 1, wherein
each of the output buffers further includes
a third transistor of the second conductivity type and a fourth transistor of the first conductivity type provided in parallel with each other between a third power supply node and a second node, and
a second resistor provided between the second node and the output node,
the first transistor is provided between the first power supply node and a first node,
the second transistor is provided between the second power supply node and the first node, and
the first resistor is provided between the first node and the output node.

13. The output circuit of claim 1, wherein
each of the output buffers further includes
a second resistor provided between a third power supply node and a second node, and
a third transistor of the second conductivity type and a fourth transistor of the first conductivity type provided in parallel with each other between the second node and the output node,
the first power supply node and the second power supply node are mutually connected via a fourth power supply node,
the first resistor is provided between the fourth power supply node and a first node, and
the first transistor and the second transistor are provided in parallel with each other between the first node and the output node.

14. The output circuit of claim 1, wherein
activation or deactivation of each of the output drive circuits is selected based on a second control signal input into the output drive circuit.

15. The output circuit of claim 1, wherein
activation or deactivation of each of the output buffers is selected based on a third control signal input into the output buffer.

16. The output circuit of claim 15, wherein
some of the plurality of output buffers is in an operable state irrespective of the third control signal.
